(19) United States
(12) Patent Application Publication
(10) Pub. No.: US 2007/0222028 A1
(43) Pub. Date: Sep. 27, 2007

(54) eFuse and method of manufacturing eFuse

(75) Inventors: Yoshihiro Matsuoka, Kawasaki (JP); Hideya Matsuyama, Kawasaki (JP); Toyoji Sawada, Kawasaki (JP); Jun Nagayama, Kawasaki (JP); Takashi Suzuki, Kawasaki (JP); Masahiro Sueda, Kawasaki (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignee: FUJITSU LIMITED, Kawasaki (JP)

(21) Appl. No.: 11/498,748

(22) Filed: Aug. 4, 2006

(30) Foreign Application Priority Data
Mar. 27, 2006 (JP) 2006-085469

(51) Int. Cl. H01L 29/00

(52) U.S. Cl. 257/529

(57) ABSTRACT

A silicide region includes a first contact region, a fuse region having a narrower longitudinal width than that of the first contact region, and a second contact region provided on an opposite side of the fuse region with respect to the first contact region. A non-silicide region is provided at a position adjacent to a non-fuse-contacting side that is opposite to a side on which the second contact region in contact with the fuse region.

### CROSS-REFERENCE TO RELATED APPLICATIONS

This application is based upon and claims the benefit of priority from the prior Japanese Patent Application No. 2006-085469, filed on Mar. 27, 2006, the entire contents of which are incorporated herein by reference.

### BACKGROUND OF THE INVENTION

1. Field of the Invention

The present invention relates to a technology of an eFuse.

2. Description of the Related Art

In recent years, an eFuse is drawing attention. In the eFuse, electromigration in which metal atoms in silicide migrate due to a high current density is utilized to vary resistance between electrodes, thereby controlling data writing (for example, U.S. Pat. Nos. 5,969,404, 6,258,700, 6,323,535, 6,337,507, 6,433,404, and 6,624,499). With the eFuse, a chip can be repeatedly used without causing any damage to other portions in the chip, unlike the technique in which a meltdown fuse is mounted in the chip.

FIG. 1 is a cross-section of a conventional eFuse. As shown in FIG. 1, a gate oxide film 106 indicated by slanted lines and a poly-silicon layer 103 on the film 106 are present on a semiconductor substrate (Si, STI). A silicide layer 101 is formed on the poly-silicon layer 103 such that the silicide layer 101 connects the poly-silicon layer 103 with contacts 104-1, 104-2. Wiring portions 105 (105-1, 105-2) are formed on the contacts 104 (104-1, 104-2).

FIG. 2 is a plan view of the conventional eFuse. A portion indicated by slanted lines in FIG. 2 is the silicide region 101. The silicide region 101 includes a first contact region 107, a fuse region 108 having a narrower width than that of the first contact region 107, and a second contact region 109 provided on the side opposite to the first contact region 107 side to sandwich the fuse region 108 with the first contact region 107.

FIG. 3A is a cross-section of a conventional eFuse before blowing. FIG. 3B is a cross-section of a conventional eFuse after blowing. Referring to FIG. 3A, when a high current is flowed from the wiring portion 105-1 into the silicide 101 formed on the upper layer side in the poly-silicon layer 103, electromigration is generated in the silicide 101 region through the contact 104-1.

In other words, the metal atoms in the silicide 101 migrate in a direction opposite to the direction of the current (that is, the direction from the contact 104-1 side to the contact 104-2 side) due to the high current density. Thus, the resistance value of the silicide region 101, which is altered by the electromigration, between the wiring portion 105-1 and the wiring portion 105-2 is varied.

At this time, as shown in FIG. 3B, a back-flow effect may be generated, and when this effect is generated, the metal atoms that have once migrated in a direction (direction toward the contact 104-2) opposite to the direction toward the side (the contact 104-1 side) toward which the current has been once flowed may return to the contact 104-1 side. Therefore, the electromigration is not sufficiently caused. In other words, the metal atoms can not migrate sufficiently. Thus, the variation of the resistance of the silicide region 101 that connects the wiring 105-1 and the wiring 105-2 is insufficient, and the fuse can not act of a fuse.

### SUMMARY OF THE INVENTION

It is an object of the present invention to at least solve the above problems.

An eFuse according to one aspect of the present invention includes a first contact region; a second contact region; a fuse region provided between the first contact region and the second contact region and configured to connect the first contact region and the second contact region; and a non-silicide region arranged in at least a part of region adjacent to the second contact region.

An eFuse according to another aspect of the present invention includes a first contact region; a second contact region; a fuse region provided between the first contact region and the second contact region and configured to connect the first contact region and the second contact region; and a non-silicide region arranged in at least a part of region adjacent to the fuse region.

A method according to still another aspect of the present invention is of manufacturing an eFuse. The method includes forming a poly-silicon layer; forming a silicon oxide layer in a predetermined position on the poly-silicon layer; forming a metal film on the poly-silicon layer and the silicon oxide layer; and applying an annealing process on the metal film to form a silicide region on an upper layer of the poly-silicon layer.

The other objects, features, and advantages of the present invention are specifically set forth in or will become apparent from the following detailed description of the invention when read in conjunction with the accompanying drawings.

### BRIEF DESCRIPTION OF THE DRAWINGS

FIG. 1 is a cross-section of a conventional eFuse;

FIG. 2 is a plan view of the conventional eFuse;

FIG. 3A is a cross-section of the conventional eFuse before blowing; and

FIG. 3B is a cross-section of the conventional eFuse after blowing.

FIG. 4 is a cross-section of an eFuse according to an embodiment of the present invention;

FIG. 5 is a cross-section of an eFuse according to an example of the embodiment;

FIG. 6A is a plan view of an eFuse according the example;

FIG. 6B illustrates another example of the eFuse according the embodiment;

FIG. 7 illustrates still another example of the eFuse according the embodiment;

FIG. 8A is a schematic for illustrating a manufacturing process of the eFuse according to the embodiment;

FIG. 8B is a schematic for illustrating the manufacturing process of the eFuse according to the embodiment;

FIG. 8C is a schematic for illustrating the manufacturing process of the eFuse according to the embodiment;

FIG. 8D is a schematic for illustrating the manufacturing process of the eFuse according to the embodiment;

FIG. 8E is a schematic for illustrating the manufacturing process of the eFuse according to the embodiment;

FIG. 8F is a schematic for illustrating the manufacturing process of the eFuse according to the embodiment;

FIG. 9 illustrates still another example of the eFuse according to the embodiment;

FIG. 10 illustrates still another example of the eFuse according the embodiment;

FIG. 11 illustrates still another example of the eFuse according to the embodiment;

FIG. 12 illustrates still another example of the eFuse according to the embodiment;

FIG. 13 illustrates still another example of the eFuse according to the embodiment;

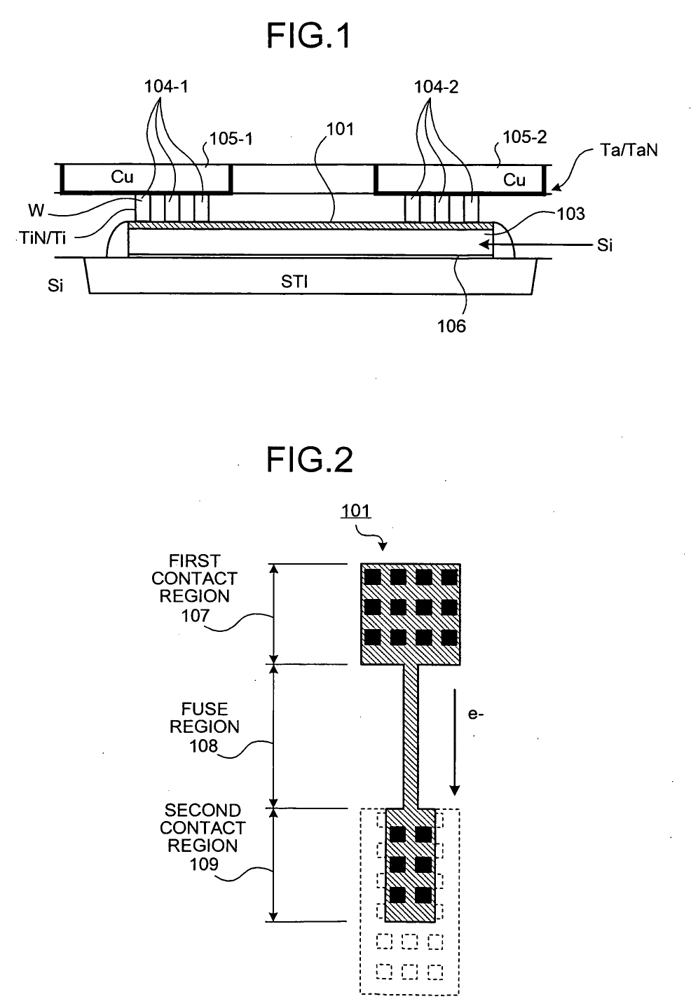

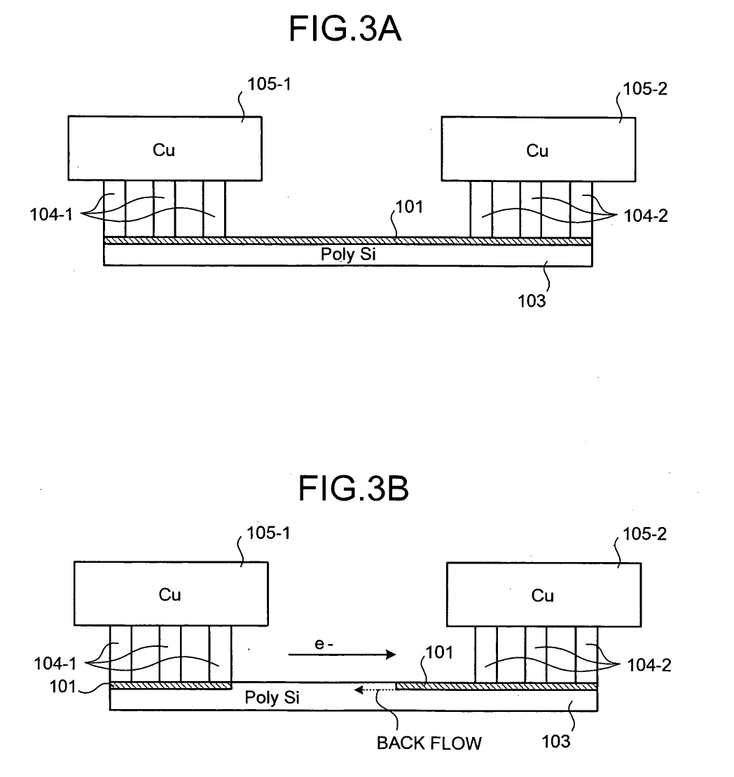

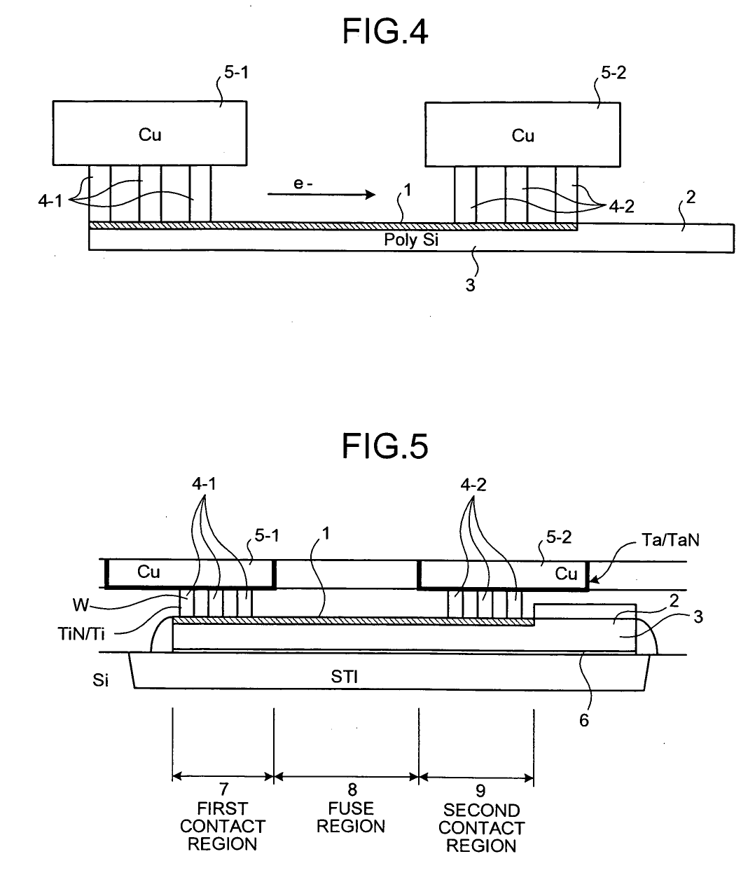

### DETAILED DESCRIPTION OF THE PREFERRED EMBODIMENTS

Exemplary embodiments according to the present invention will be explained in detail below with reference to the accompanying drawings.

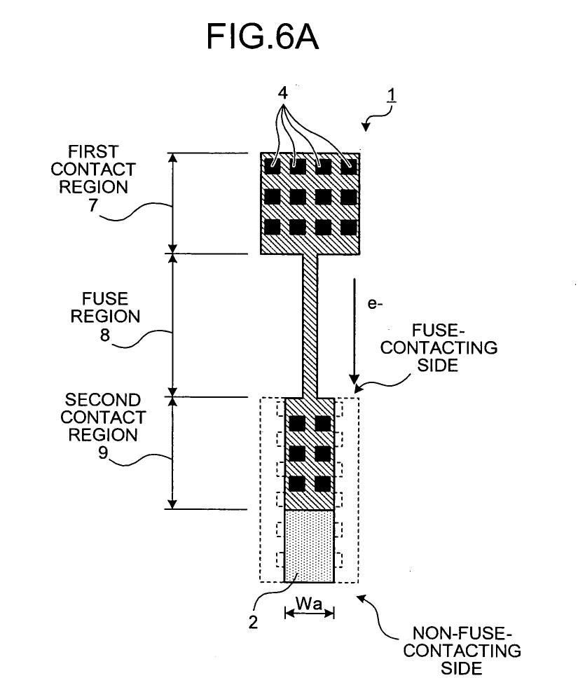

FIG. 4 is a cross-section of an eFuse according to an embodiment of the present invention. As shown in FIG. 4, a non-silicide region 2 is provided in the vicinity portion adjacent to a silicide 1 formed on the upper layer side in a poly-silicon (Poly-Si) layer 3.

The back-flow effect is originally an effect that metal atoms that have migrated due to the electromigration collide with other metal atoms and the metal atoms having no places to go return to the original positions thereof. Therefore, as a measure against the effect, by providing the non-silicide region 2, the metal atoms having no places to go are pushed out sequentially. Therefore, metal atoms present near the non-silicide migrate to the non-silicide region 2. It can be considered that, thus occurrence of the back-flow effect can be prevented efficiently.

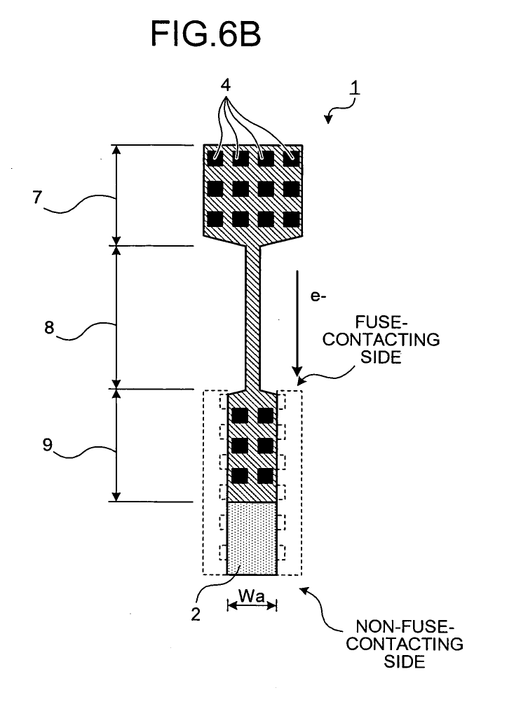

FIG. 5 is a cross-section for illustrating an example of an eFuse according to an example of the embodiment. As shown in FIG. 5, a gate oxide film 6 and a poly-silicon layer 3 on the film 6 are present on a semiconductor substrate (Si, STI). A silicide layer 1 is formed in the upper layer side in the poly-silicon layer 3 such that the silicide layer 1 connects the poly-silicon layer 3 with a contact group 4-1 and a contact group 4-2. A wiring portion 5-1 is formed on the contact group 4-1 and a wiring portion 5-2 is formed on the contact group 4-2, respectively. The silicide 1 is, for example, cobalt (Co) silicide, titanium (Ti) silicide, Nickel (Ni) silicide, etc.

The contact groups 4-1, 4-2 are made of a material such as, for example, tungsten (W), etc., and are coated by titanium nitride (TiN) or titanium (Ti). The wiring portions 5-1, 5-2 are made of a material such as, for example, copper (Cu), etc., and are coated by titan (Ta) or titan nitride (TaN). In FIG. 5, an approximately same layer as the silicide 1, that is, the upper layer side in the poly-silicon layer 3 (in FIG. 5, the right side of a same layer as the silicide 1) is the non-silicide region 2.

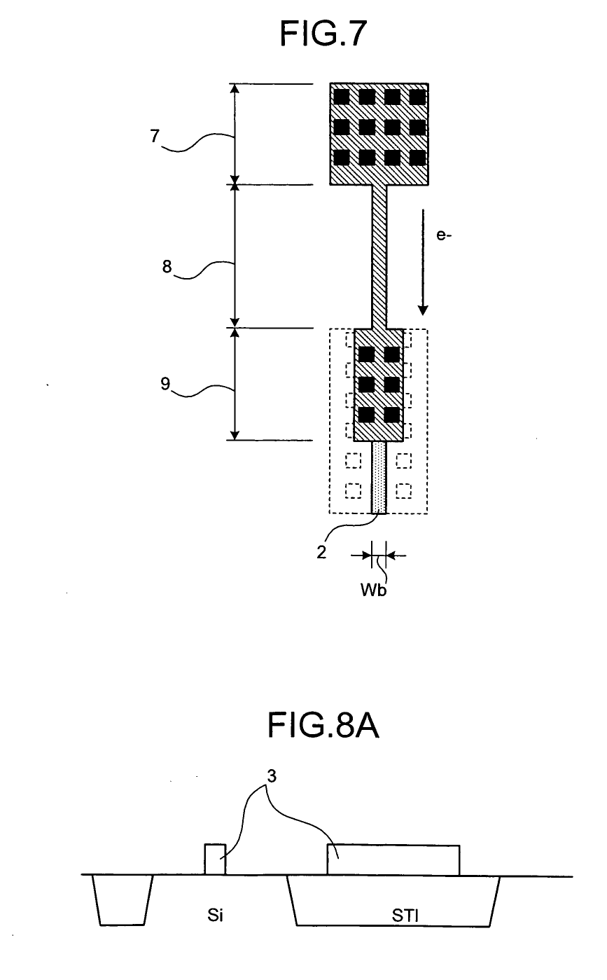

FIG. 6A is a plan view of the eFuse according to the example. A portion indicated by slanted lines is the silicide (region) 1 and the silicide region 1 consists of a first contact region 7, a fuse region 8 having a narrower longitudinal width than that of the first contact region 7, and a second contact region 9 provided on the side opposite to the first contact region 7 to sandwich the fuse region 8 with the first contact region 7.

The non-silicide region 2 is provided at a position adjacent to the side (on the non-fuse-contacting side) that is opposite to the side of the second contact region 9 in contact with the fuse region 8. Thus, when metal atoms in the silicide of the fuse region 8 have migrated, metal atoms in the silicide of the second contact region 9 collide with the metal atoms having migrated from the fuse region 8 and migrate toward the non-silicide region 2. Thereby, it is considered that the back-flow effect can be avoided.

In the example shown in FIG. 6B, the shapes of the first contact region 7 and the second contact region 9 are different from those of FIG. 6A. Though the shapes are squares in FIG. 6A, the shapes are made hexagons by removing the corners in contact with a face of the fuse region 8 in FIG. 6B. Thus it is considered that the electromigration can take place more efficiently. Though showing in drawings is omitted in other detailed examples below, the first contact region 7 and the second contact region 9 may be polygons (especially, hexagons) in stead of squares.

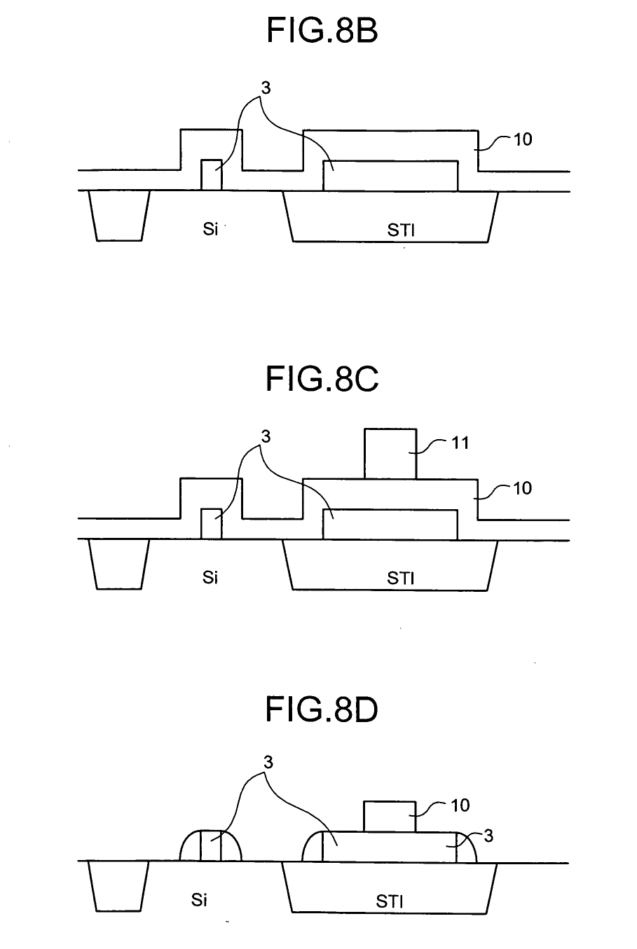

FIG. 7 illustrates still another example of the eFuse according the embodiment. In the example shown in FIG. 6, the width perpendicular to the longitudinal direction of the fuse region 8 of the second contact region 9 and the width of the non-silicide region 2 are approximately equal (“Wa”). However, the widths are not limited to such a case and, for example, as shown in FIG. 7, the width of the non-silicide region 2 may be approximately equal (“Wb”) to the width perpendicular to the longitudinal direction of the fuse region 8. It is considered that the non-silicide region 2 is positioned on an extension of the fuse region 8.

It can be considered that, in this manner, as to the second contact region 9, by providing the non-silicide region 2 on the side opposite to the fuse region 8 as a receiving pan for the metal atoms bounced out by collision with metal atoms that have been pushed out from the fuse region 8, the back-flow effect in the fuse region 8 can be effectively prevented.

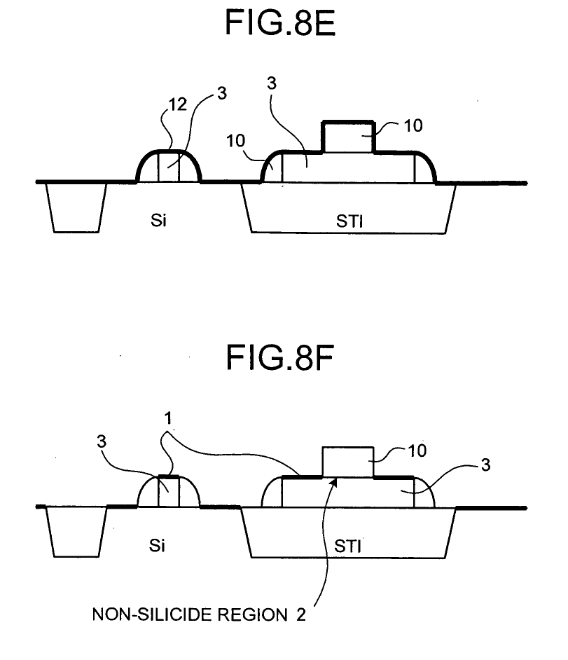

FIGS. 8A to 8F are schematics for illustrating a manufacturing process of the eFuse according to the embodiment. As shown in FIG. 8A, the poly-silicon layer 3 is formed on the semiconductor substrate (Si, STI). As shown in FIG. 8B, a silicon oxide (SiO₂) layer 10 is formed on the poly-silicon layer 3 formed in FIG. 8A. A photo-resist 11 is formed on the silicon oxide layer 10. Etching is performed. The photo-resist 11 is removed as shown in FIG. 8C. Thereafter, the silicon oxide layer 10 is left at a predetermined position on the poly-silicon layer 3 as shown in FIG. 8D.

As shown in FIG. 8E, a metal (for example, cobalt, etc.) film 12 is vapor-deposited in the state shown in FIG. 8D and, thereafter, an anneal process is performed. The result is shown in FIG. 8F and is that the silicide region 1 is divided and present only as portions on the poly-silicon layer 3 and a portion beneath the silicon oxide 10 of portions on the poly-silicon layer 3 is the non-silicide region 2.

As described above, the non-silicide region 2 can be easily formed by using the photo-resist 11. However, the forming method of the non-silicide region 2 is not limited to the above method. For example, by removing silicide of a corresponding portion by etching, etc., after forming the silicide 1 all over the upper layer side in the poly-silicon layer 3, the portion may also be formed into the non-silicide region 2.

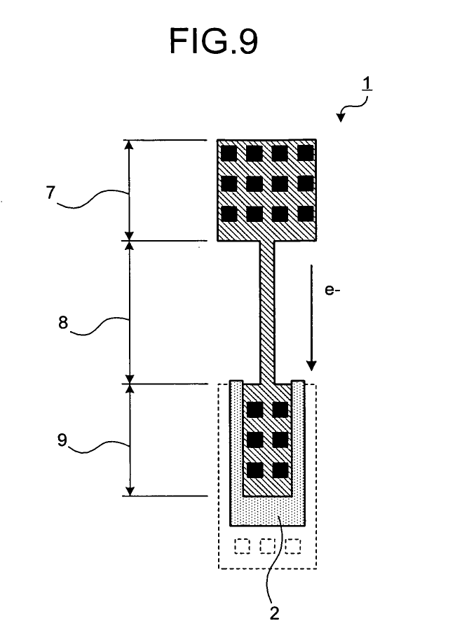

FIGS. 9 to 13 illustrate still another example of the eFuse according to the embodiment. In the example shown in FIG. 9, a region surrounding the second contact region 9, especially regions on both sides (hereinafter, “side regions”) to the non-fuse region is the non-silicide region 2. Thereby, the case where the metal atoms migrate toward the side regions can be coped with. Both of the non-fuse region and the side regions are non-silicide region 2 in FIG. 9, only the side regions may be non-silicide region 2. In FIG. 9, how wide the width of the non-silicide region 2 should be may be determined during designing considering the performance of the eFuse.

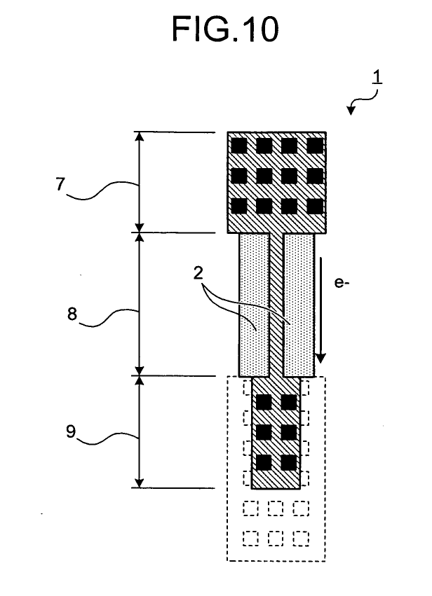

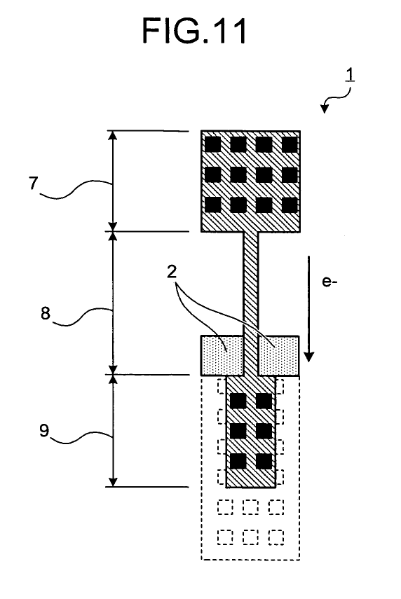

In the examples shown in FIGS. 10 and 11, regions on both sides of and adjacent to the fuse region 8 are non-silicide regions 2. It is considered that, thus the metal atoms returned by the back-flow effect can be caused to migrate to the regions on both sides. While the entire regions on both sides of and adjacent to the fuse region 8 are non-silicide region 2 in FIG. 10, only portions of regions on the second contact region 9 side of the regions on both sides of the fuse region 8 are non-silicide region 2. To which position on both sides of the fuse region 8 the non-silicide region 2 should be extended and how wide the non-silicide region 2 should be may be determined during designing considering the performance of the eFuse. Though the regions on both sides are non-silicide regions 2 in FIGS. 10 and 11, only either one may be the non-silicide region 2.

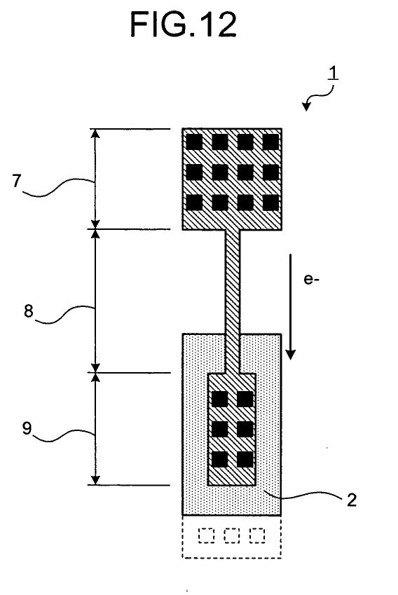

In the example shown in FIG. 12, a region formed by integrating the fuse side region, the non-fuse-connected side region, and the side regions is the non-silicide region 2. It is considered that, by surrounding completely the second contact region 9 as above, the back-flow effect causing the metal atoms to flow through the fuse region 8 to the first contact region 7 can be more securely prevented. How wide the width of the non-silicide region 2 should be may be determined during designing considering the performance of the eFuse.

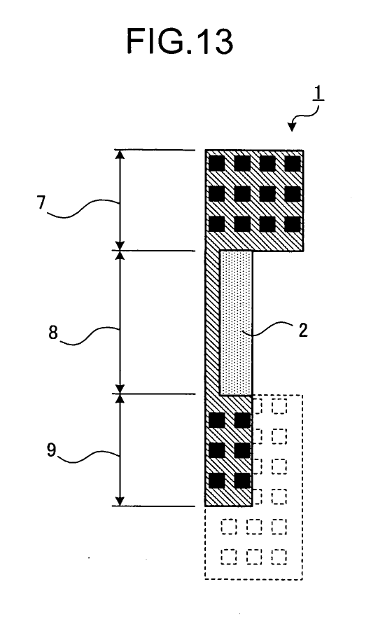

In the example shown in FIG. 13, the fuse region 8 is disposed being brought to same sides of the first contact region 7 and the second contact region 9, and a region on the side adjacent to the fuse region 8 and on the side in an opposite direction to the direction of bringing the fuse region 8 is the non-silicide region 2. It is considered that, in this manner, by bringing the fuse region 8 to a side, the eFuse can be manufactured more easily.

As described above, according to the embodiment, the back-flow effect can be more securely prevented.

According to the embodiments described above, it is possible to effectively prevent a back-flow.

Although the invention has been described with respect to a specific embodiment for a complete and clear disclosure, the appended claims are not to be thus limited but are to be construed as embodying all modifications and alternative constructions that may occur to one skilled in the art which fairly fall within the basic teaching herein set forth.

What is claimed is:

1. An efuse, comprising:
a first contact region;
a second contact region;
a fuse region provided between the first contact region and the second contact region and configured to connect the first contact region and the second contact region; and
a non-silicide region arranged in at least a part of region adjacent to the second contact region.

2. The eFuse according to claim 1, wherein, the non-silicide region is arranged on a side on which the second contact region is in contact with the fuse region.

3. The eFuse according to claim 1, wherein, the non-silicide region is arranged on a side opposite to a side on which the second contact region is in contact with the fuse region.

4. The eFuse according to claim 3, wherein the non-silicide region is configured to have approximately same width as a width of the fuse region in a direction perpendicular to a longitudinal direction thereof.

5. The eFuse according to claim 3, wherein the non-silicide region is configured to have approximately same width as a width of the fuse region in a direction perpendicular to a longitudinal direction thereof, and is arranged on an extension of the fuse region.

6. The eFuse according to claim 1, wherein the non-silicide region is arranged on at least one of sides of the second contact region, the sides with respect to a side on which the second contact region is in contact with the fuse region and a side opposite to the side on which the second contact region is in contact with the fuse region.

7. The eFuse according to claim 1, wherein the non-silicide region is arranged in at least a part of region adjacent to the fuse region.

8. The eFuse according to claim 1, wherein at least one of the first contact region and the second contact region is configured to have a polygonal shape, and one side of the polygonal shape is connected to the fuse region.

9. An eFuse, comprising:
a first contact region;
a second contact region;
a fuse region provided between the first contact region and the second contact region and configured to connect the first contact region and the second contact region; and
a non-silicide region-arranged in at least a part of region adjacent to the fuse region.

10. A method of manufacturing an eFuse, comprising:
forming a poly-silicon layer;
forming a silicon oxide layer in a predetermined position on the poly-silicon layer;
forming a metal film on the poly-silicon layer and the silicon oxide layer; and
applying an annealing process on the metal film to form a silicide region on an upper layer of the poly-silicon layer.

11. The method according to claim 10, wherein the silicon oxide layer is formed using a photo-resist.
